(19) United States
(12) Patent Application Publication
(10) Pub. No.: US 2026/0123074 A1
(43) Pub. Date: Apr. 30, 2026

(54) IMAGE SENSOR AND MANUFACTURING METHOD OF THE SAME

(71) Applicant: Samsung Electronics Co., Ltd., Suwon-si (KR)

(72) Inventors: Ji Hyun KWAK, Suwon-si (KR); Jin Young KIM, Suwon-si (KR); Ha Neul KIM, Suwon-si (KR); Chang Kyu LEE, Suwon-si (KR)

(73) Assignee: Samsung Electronics Co., Ltd., Suwon-si (KR)

(21) Appl. No.: 19/280,544

(22) Filed: Jul. 25, 2025

(30) Foreign Application Priority Data
Oct. 25, 2024 (KR) 10-2024-0147176

(51) Int. Cl. H10F 39/00; H10F 39/18

(52) U.S. Cl. CPC H10F 39/8053; H10F 39/014; H10F 39/024; H10F 39/182; H10F 39/8057; H10F 39/8063; H10F 39/807

(57) ABSTRACT

Provided is an image sensor. The image sensor includes a first region and a second region near the first region and including first and second surfaces, which are opposite to each other, a plurality of unit pixel regions including photoelectric conversion layers inside the substrate, grid patterns arranged on the first surface of the substrate in the first region, a first metal layer disposed between the grid patterns on the first surface of the substrate in the first region, a metal structure disposed to be spaced apart from the grid patterns on the first surface of the substrate in the second region, and a color filter disposed on the grid patterns and the first metal layer.

### CROSS-REFERENCE TO RELATED APPLICATION

This application claims priority from Korean Patent Application No. 10-2024-0147176 filed on Oct. 25, 2024 in the Korean Intellectual Property Office and all the benefits accruing therefrom under 35 U.S.C. 119, the contents of which in its entirety are herein incorporated by reference.

### BACKGROUND

Some example embodiments relate to an image sensor and/or a manufacturing method of the same.

An image sensor is one of semiconductor devices that convert optical information into an electrical signal. The image sensor may include a charge coupled device (CCD) image sensor and/or a complementary metal-oxide semiconductor (CMOS) image sensor.

The image sensor may be configured in the form of a package. In this case, the package may be configured in a structure that protects or at least partly protects the image sensor and at the same time allows light to enter a photo receiving surface and/or a sensing area of the image sensor.

### SUMMARY

Some example embodiments may provide an image sensor with improved performance.

Alternatively or additionally some example embodiments may provide a manufacturing method of an image sensor with improved performance.

An image sensor according to some example embodiments includes a substrate including a first region and a second region, the substrate including first and second surfaces opposite to each other, a plurality of unit pixel regions including photoelectric conversion layers inside the substrate, grid patterns in the first region and on the first surface of the substrate, a first metal layer in the first region, on the first surface of the substrate and between the grid patterns, a metal structure on the first surface of the substrate, in the second region, and spaced apart from the grid patterns, and a color filter on the grid patterns and the first metal layer.

Alternatively or additionally an image sensor according to some example embodiments includes a substrate including a light receiving region and a light blocking region, extended in first and second directions crossing each other, a plurality of unit pixel regions including photoelectric conversion layers arranged in the first and second directions, a first metal pattern extended on some unit pixel regions adjacent to each other in the first direction, among the plurality of unit pixel regions in the light receiving region, and grid patterns exposing an upper surface of the first metal pattern in the light receiving region.

Alternatively or additionally an image sensor according to some example embodiments includes a substrate including a first region and a second region and including first and second surfaces opposite to each other, a plurality of unit pixel regions including photoelectric conversion layers inside the substrate, a surface insulating film disposed on the first surface of the substrate, grid patterns including first and second grid patterns disposed to be spaced apart from each other on the surface insulating film in the first region, a first metal layer disposed between the first and second grid patterns on the surface insulating film in the first region, a metal structure disposed to be spaced apart from the first and second grid patterns on the surface insulating film in the second region, a dielectric material layer disposed on the metal structure in the second region, and a color filter disposed on the grid patterns and the first metal layer. In the first region, one end portion of the first metal layer is in contact with the first grid pattern, and the other end portion of the first metal layer is spaced apart from the second grid pattern.

Alternatively or additionally according to some example embodiments, there is provided a method of fabricating an image sensor comprising provisioning a substrate including a photoelectric conversion layer, the substrate having a first surface and a second surface opposite to the first surface, the substrate having a light receiving region and a light blocking region, forming a surface insulating film on the first surface of the substrate, sequentially forming a first pre-barrier layer and a second pre-metal layer on the surface insulating film locally in the light blocking region, forming a third pre-metal layer on the surface insulating film in the light receiving region and on the second pre-metal layer in the light blocking region, forming a first metal layer by removing at least a portion of the first pre-metal layer and the third pre-metal layer, forming a first pre-dielectric material layer on the first metal layer in the light receiving region, and forming a second pre-dielectric material layer on the first metal layer in the light blocking region.

In some example embodiments, the method may include planarizing at least a portion of the first pre-dielectric material layer and at least a portion of the second pre-dielectric layer.

In some example embodiments, a material composition of the third pre-metal layer in the light receiving region is same as a material composition of the third pre-metal layer in the light blocking region.

The objects of example embodiments are not limited to those mentioned above and additional features of inventive concepts, which are not mentioned herein, will be clearly understood by those of ordinary skill in the art from the following description of some example embodiments.

### BRIEF DESCRIPTION OF THE DRAWINGS

FIG. 1 is a block diagram illustrating an image sensor according to some example embodiments;

FIG. 2 is a circuit view illustrating a unit pixel of an image sensor according to some example embodiments;

FIG. 3 is a layout view illustrating an image sensor according to some example embodiments;

FIG. 4 is a layout view illustrating a portion of the light receiving region of FIG. 3;

FIG. 5 is a cross-sectional view taken along line A-A of FIG. 4 and a cross-sectional view illustrating the light blocking region of FIG. 3;

FIGS. 6 to 8 are various enlarged views illustrating a region R1 of FIG. 5;

FIGS. 9 and 10 are cross-sectional views illustrating an image sensor according to some example embodiments;

FIG. 11 is an enlarged view illustrating a region R2 of FIG. 10;

FIG. 12 is a layout view illustrating an image sensor according to some example embodiments;

FIG. 13 is a layout view illustrating an image sensor according to some example embodiments;

FIG. 14 is a cross-sectional view taken along line B-B of FIG. 13;

FIGS. 15 to 22 are layout views illustrating an image sensor according to some example embodiments;

FIGS. 23 and 24 are views illustrating a conceptual layout of an image sensor according to some example embodiments;

FIGS. 25 to 29 are views illustrating intermediate steps to describe a manufacturing method of an image sensor according to some example embodiments;

FIGS. 30 to 33 are views illustrating intermediate steps to describe a manufacturing method of an image sensor according to some example embodiments;

FIGS. 34 to 36 are views illustrating intermediate steps to describe a manufacturing method of an image sensor according to some example embodiments.

### DETAILED DESCRIPTION OF EXAMPLE EMBODIMENTS

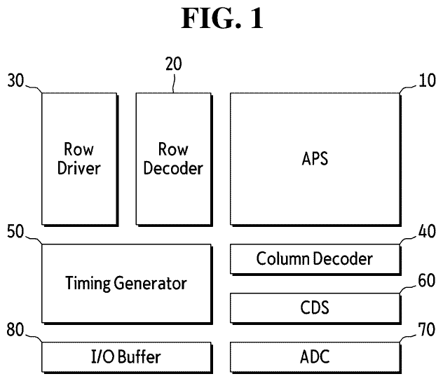

Hereinafter, an image sensor according to some example embodiments will be described with reference to FIGS. 1 to 24.

FIG. 1 is a block diagram illustrating an image sensor according to some example embodiments.

Referring to FIG. 1, the image sensor according to some example embodiments includes an active pixel sensor array (APS) 10, a row decoder 20, a row driver 30, a column decoder 40, a timing generator 50, a correlated double sampler (CDS) 60, an analog-to-digital converter (ADS) 70, and an input/output (I/O) buffer 80.

The active pixel sensor array 10 includes a plurality of unit pixels that are two-dimensionally arranged, and may convert an optical signal into an electrical signal, e.g., by generating one or more electron-hole pairs (EHP's). The active pixel sensor array 10 may be driven by a plurality of driving signals, such as a pixel selection signal, a reset signal and a charge transmission signal from the row driver 30. Alternatively or additionally, the electrical signal converted by the active pixel sensor array 10 may be provided to the correlated double sampler 60.

The row driver 30 may provide a plurality of driving signals for driving the plurality of unit pixels to the active pixel sensor array 10 in accordance with a result decoded by the row decoder 20. When the unit pixels are arranged in the form of a matrix, driving signals may be provided for each row.

The timing generator 50 may provide a timing signal and a control signal to the row decoder 20 and the column decoder 40.

The correlated double sampler 60 may hold and sample the electrical signal by receiving the electrical signal generated by the active pixel sensor array 10. The correlated double sampler 60 may doubly sample a specific noise level and a signal level by the electrical signal to output a difference level corresponding to a difference between the noise level and the signal level.

The analog-to-digital converter 70 may convert an analog signal corresponding to the difference level output from the correlated double sampler 60 into a digital signal and output the digital signal.

The input/output buffer 80 latches the digital signal, and may sequentially output the latched signal to an image signal processor (not shown) as the digital signal in accordance with the decoding result of the column decoder 40.

Each of the elements illustrated in FIG. 1 may communicate with any other element in FIG. 1, over a bus such as a wired bus and/or a wireless bus, to send and/or receive information such as data and/or commands. The information may be sent and/or received in a one-way and/or two-way and/or broadcast manner, and may be formatted in various formats such as but not limited to digital and/or analog information. The information may be sent serially and/or in a parallel manner. Example embodiments are not limited thereto.

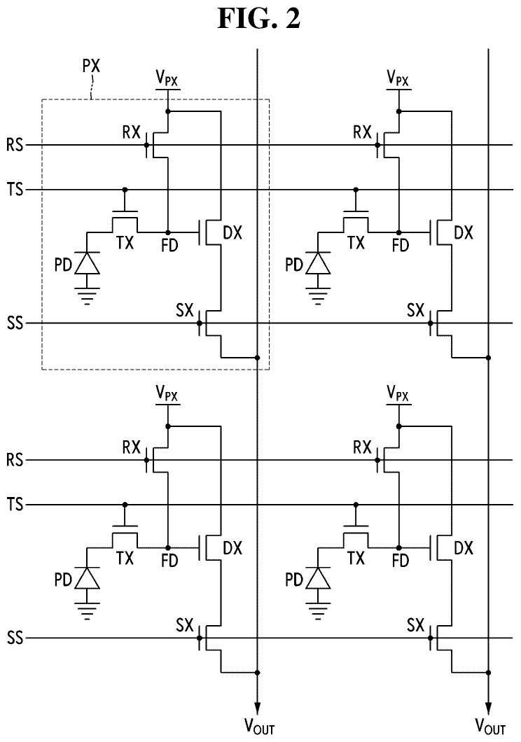

FIG. 2 is a circuit view illustrating a unit pixel of an image sensor according to some example embodiments.

Referring to FIG. 2, the image sensor according to some example embodiments includes a plurality of unit pixels PX.

The plurality of unit pixels PX may be arranged two-dimensionally (e.g., in the form of a matrix). A number of rows of the matrix may be the same as, or different from (e.g., greater than or less than) a number of columns in the matrix. Each unit pixel PX may include a photoelectric conversion layer PD, a transmission transistor TX, a floating diffusion region FD, a reset transistor RX, a drive transistor DX and a selection transistor SX.

The photoelectric conversion layer PD may generate charges, e.g., electron-hole pairs, in proportion to the amount of light incident from the outside. The photoelectric conversion layer PD may be coupled with the transmission transistor TX that transmits charges, which are generated and then accumulated, to the floating diffusion region FD. Since the floating diffusion region FD is a region for converting charges into voltages and has a parasitic capacitance, the charges may be cumulatively stored in the floating diffusion region FD.

One end (e.g., a source end or a drain end) of the transmission transistor TX may be connected to the photoelectric conversion layer PD, and another end (e.g., the other of the source end or the drain end) of the transmission transistor TX may be connected to the floating diffusion region FD. The transmission transistor TX may be formed of a transistor driven by a bias such as by a predetermined bias (e.g., transmission signal TS). For example, the transmission transistor TX may transmit the charges generated from the photoelectric conversion layer PD to the floating diffusion region FD in accordance with the transmission signal TS.

The drive transistor DX may be provided as a source follower buffer amplifier. The drive transistor DX may amplify a change in an electric potential of the floating diffusion region FD that has received the charges from the photoelectric conversion layer PD, and may output the amplified change in the electric potential to an output line VOUT. When the drive transistor DX is turned on, a pixel power voltage VPX provided to a drain of the drive transistor DX may be transferred to a drain region of the selection transistor SX.

The selection transistor SX may select a unit pixel to be read in a row unit. The selection transistor may be a transistor that is driven by a selection line that applies a predetermined bias (e.g., row selection signal SS).

The reset transistor RX may reset, e.g., may periodically reset the floating diffusion region FD. The reset transistor RX may be a transistor driven by a reset line that applies a bias such as a predetermined bias (e.g., reset signal RS). When the reset transistor RX is turned on by the reset signal RS, an electrical potential, e.g., a predetermined electrical potential provided to the drain of the reset transistor RX, for example, the pixel power voltage VPX may be transferred to the floating diffusion region FD so that the floating diffusion region FD may be reset.

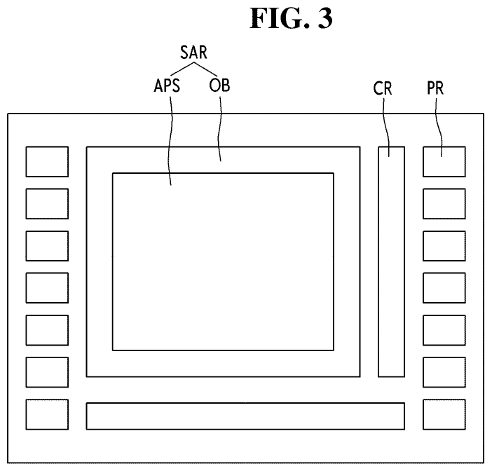

FIG. 3 is a layout view illustrating an image sensor according to some example embodiments.

Referring to FIG. 3, the image sensor according to some example embodiments includes a sensor array region SAR, a connection region CR and a pad region PR.

The sensor array region SAR may include a region corresponding to the active pixel sensor array 10 of FIG. 1. For example, a plurality of unit pixels arranged two-dimensionally (for example, in the form of a matrix) may be formed in the sensor array region SAR.

The sensor array region SAR may include a light receiving region APS and a light blocking region OB. Active pixels for receiving light to generate an active signal may be arranged in the light receiving region APS. Optical black pixels for shielding light to generate an optical black signal may be arranged in the light blocking region OB. The light blocking region OB may be formed along the periphery of the light receiving region APS, but this is only an example.

In some embodiments, dummy pixels (not shown) may be formed in the light receiving region APS adjacent to the light blocking region OB.

The connection region CR may be formed in the periphery of the sensor array region SAR. The connection region CR may be formed at one side of the sensor array region SAR, but this is only an example. Lines may be formed in the connection region CR to transmit and receive the electrical signal of the sensor array region SAR.

The pad region PR may be formed in the periphery of the sensor array region SAR. The pad region PR may be formed to be adjacent to an edge of the image sensor according to some example embodiments, but this is only an example. The pad region PR may be connected to an external device or the like to transmit and receive an electrical signal between the image sensor according to some example embodiments and the external device.

In FIG. 3, the connection region CR is shown as being interposed between the sensor array region SAR and the pad region PR, but is only an example. There may be various arrangements of the sensor array region SAR, the connection region CR and the pad region PR as necessary.

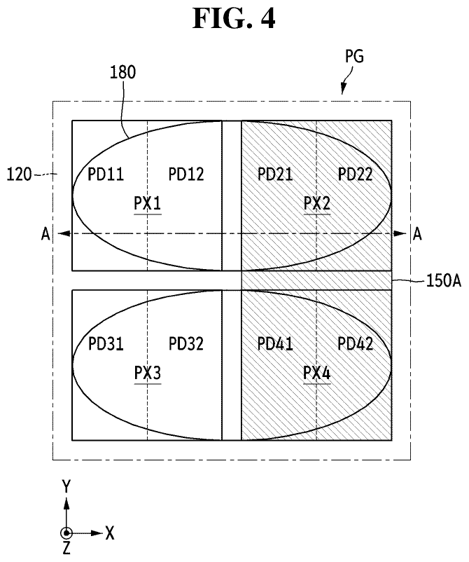

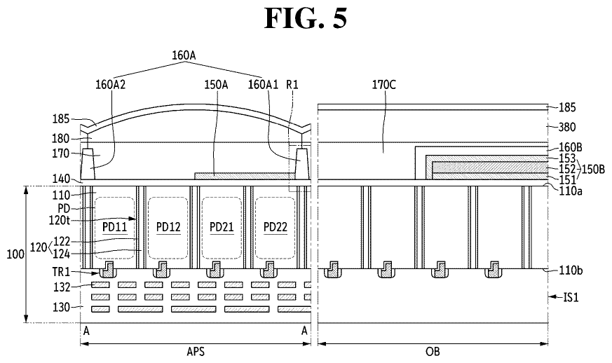

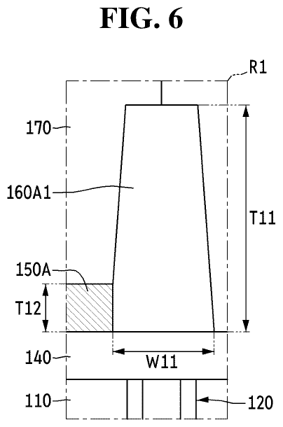

FIG. 4 is a layout view illustrating a portion of the light receiving region of FIG. 3. FIG. 5 is a cross-sectional view taken along line A-A of FIG. 4 and a cross-sectional view illustrating the light blocking region of FIG. 3. FIGS. 6 to 8 are various enlarged views illustrating a region R1 of FIG. 5.

Referring to FIGS. 4 and 5, an image sensor according to some example embodiments includes a substrate 110, a separation pattern 120, a surface insulating film 140, a first metal layer 150A, grid patterns 160A, a metal structure 150B, a dielectric material layer 160B, a first color filter 170, and a micro-lens 180.

A first surface 110a and a second surface 110b of the substrate 110, which will be described later, may be extended in a first direction X and a second direction Y, which cross to be perpendicular to each other, respectively. A third direction Z may mean a height direction perpendicular to each of the first direction X and the second direction Y.

A pixel group PG may include a number of unit pixel regions, such as four unit pixel regions PX1, PX2, PX3 and PX4 arranged in the form of a matrix and disposed on the same color filter. The four unit pixel regions PX1, PX2, PX3 and PX4 may include first and second unit pixel regions PX1 and PX2, and third and fourth unit pixel regions PX3 and PX4.

The first and second unit pixel regions PX1 and PX2 are adjacent to each other in the first direction X, and may share one micro-lens 180. The third and fourth unit pixel regions PX3 and PX4 are spaced apart from the first and second unit pixel regions PX1 and PX2 in the second direction Y, respectively, and may be adjacent to each other in the first direction X. The third and fourth unit pixel regions PX3 and PX4 may share another micro-lens different from the micro-lens 180 shared by the first and second unit pixel regions PX1 and PX2, but example embodiments are not limited thereto.

Although not shown in detail, each micro-lens 180 may be disposed on each of the plurality of unit pixel regions PX1 to PX4.

Alternatively or additionally, although not shown in detail, the plurality of pixel groups PG may be arranged two-dimensionally (e.g., in the form of a matrix) on a plane including the first direction X and the second direction Y.

Each of the plurality of unit pixel regions PX1, PX2, PX3 and PX4 may include a plurality of photoelectric conversion layers PD11 to PD42.

The first unit pixel region PX1 may include (1_1)th and (1_2)th photoelectric conversion layers PD11 and PD12 adjacent to each other in the first direction X. Long sides of each of the (1_1)th and (1_2)th photoelectric conversion layers PD11 and PD12 may be extended in the second direction Y, and short sides thereof may be extended in the first direction X.

The second unit pixel region PX2 may include (2_1)th and (2_2)th photoelectric conversion layers PD21 and PD22 adjacent to each other in the first direction X. Long sides of each of the (2_1)th and (2_2)th photoelectric conversion layers PD21 and PD22 may be extended in the second direction Y, and short sides thereof may be extended in the first direction X.

The third unit pixel region PX3 may include (3_1)th and (3_2)th photoelectric conversion layers PD31 and PD32 adjacent to each other in the first direction X. Long sides of each of the (3_1)th and (3_2)th photoelectric conversion layers PD31 and PD32 may be extended in the second direction Y, and short sides thereof may be extended in the first direction X.

The fourth unit pixel region PX4 may include (4_1)th and (4_2)th photoelectric conversion layers PD41 and PD42 adjacent to each other in the first direction X. Long sides of each of the (4_1)th and (4_2)th photoelectric conversion layers PD41 and PD42 may be extended in the second direction Y, and short sides thereof may be extended in the first direction X.

The first substrate 110 may be or may include a semiconductor substrate. For example, the first substrate 110 may be or include a bulk silicon or a silicon-on-insulator (SOI). The first substrate 110 may be a silicon substrate, and/or may include other materials such as one or more of silicon germanium, indium antimonide, lead telluride, indium arsenide, indium phosphide, gallium arsenide or gallium antimonide. Alternatively or additionally, the first substrate 110 may be an epitaxial layer formed on a base substrate.

The first substrate 110 may include a first surface 110a and a second surface 110b, which are opposite to each other. In some example embodiments described later, the first surface 110a may be referred to as a back side of the first substrate 110, and the second surface 110b may be referred to as a front side of the first substrate 110. In some example embodiments, the first surface 110a of the first substrate 110 may be a light receiving surface on which light is incident. For example, the image sensor according to some example embodiments may be or include (or be included in) a backside illumination (BSI) image sensor.

A plurality of photoelectric conversion layers PD may be formed on the substrate 110 of the sensor array region SAR. For example, as shown in FIG. 4, the plurality of photoelectric conversion layers PD arranged two-dimensionally (e.g., in the form of a matrix) on a plane including the first direction X and the second direction Y may be formed in the substrate 110 of the light receiving region APS.

The photoelectric conversion layer PD may generate charges, e.g., electrons or holes or electron-hole pairs, in proportion to the amount of light incident from the outside. In some example embodiments, the photoelectric conversion layer PD may not be formed in at least a portion of the light blocking region OB. For example, the photoelectric conversion layer PD may be formed in the substrate 110 of the light blocking region OB adjacent to the light receiving region APS, but may not be formed in the substrate 110 of the light blocking region OB spaced apart from the light receiving region APS.

The photoelectric conversion layer PD may include at least one of, for example, a photo diode, a photo transistor, a photo gate, a pinned photo diode, an organic photo diode, a quantum dot or their combination, but is not limited thereto.

Each of the plurality of unit pixel regions PX1 to PX4 may include a first electronic device TR1. In some example embodiments, the first electronic device TR1 may be disposed on the second surface 110b of the first substrate 110. The first electronic device TR1 may be connected to the photoelectric conversion layer PD to constitute various transistors for processing an electrical signal. For example, the first electronic device TR1 may be or may correspond to a transistor such as the transmission transistor, the reset transistor, the source follower transistor or the selection transistor.

In some example embodiments, the first electronic device TR1 may include a vertical transmission transistor. For example, a portion of the first electronic device TR1 constituting the aforementioned transmission transistor TX may be extended into the first substrate 110. The transmission transistor TX may reduce an area of a unit pixel to enable high integration of the image sensor.

The separation pattern 120 may be formed in the substrate 110 of the sensor array region SAR. For example, the separation pattern 120 may be formed by burying an insulating material in a deep trench formed by patterning the substrate 110.

The separation pattern 120 may be disposed between the photoelectric conversion layers PD. The separation pattern 120 may separate regions, in which the photoelectric conversion layers PD are disposed, from each other. Also, when viewed in a plan view, the separation pattern 120 may be formed to surround each of the unit pixel regions PX1 to PX4 in which the photoelectric conversion layers PD are disposed.

In some example embodiments, the separation pattern 120 may pass through, e.g., entirely through, the substrate 110. For example, as shown in FIG. 5, the separation pattern 120 may be extended from the first surface 110a to the second surface 110b in the third direction Z.

In some example embodiments, the separation pattern 120 may include an insulating spacer film 122 and a filling conductive film 124. For example, a separation pattern trench 120t may be formed in the substrate 110. The insulating spacer film 122 may be extended along a side of the separation pattern trench 120t. The filling conductive film 124 may be formed on the insulating spacer film 122 to fill the remaining region of the separation pattern trench 120t.

In some example embodiments, the insulating spacer film 122 may include an oxide film having a refractive index lower than that of the substrate 110. The insulating spacer film 122 may include at least one of silicon oxide, aluminum oxide, tantalum oxide or their combination, but is not limited thereto. The insulating spacer film 122 having a refractive index lower than that of the substrate 110 may refract and/or reflect light obliquely incident on the photoelectric conversion layer PD. Also, the insulating spacer film 122 may prevent photocharges generated in a specific unit pixel region by incident light from moving to an adjacent unit pixel region by random drift. For example, the insulating spacer film 122 may improve quality of the image sensor according to some example embodiments by improving a light receiving rate of the photoelectric conversion layer PD.

In some example embodiments, the filling conductive film 124 may include a conductive material. For example, the filling conductive film 124 may include poly silicon (poly Si), but is not limited thereto. In some example embodiments, a ground voltage or a negative voltage may be applied to the filling conductive film 124 containing a conductive material. Thus, an electrostatic discharge (ESD) bruise defect of the image sensor according to some example embodiments may be effectively prevented or reduced in likelihood of occurrence and/or in impact from occurrence. In this case, the ESD bruise defect refers to a phenomenon in which charges generated by the ESD or the like are accumulated in a surface (e.g., the first surface 110a) of the substrate and thus a stain such as a bruise is generated in an image that is generated.

The first wiring structure IS1 may be formed on the substrate 110. For example, the first wiring structure IS1 may cover the second surface 110b of the substrate 110. The substrate 110 and the first wiring structure IS1 may constitute a first substrate structure 100.

The first wiring structure IS1 may include one or a plurality of wirings. For example, the first wiring structure IS1 may include a first inter-wire insulating layer 130 and a first wiring 132 in the first inter-wire insulating layer 130. In FIG. 5, the number of layers and/or the arrangement of wirings and/or the thicknesses constituting the first wiring structure IS1 are only an example. The first inter-wire insulating layer 130 may include at least one of, for example, silicon oxide, silicon nitride, silicon oxynitride, or a low dielectric constant (low-k) material having a dielectric constant lower than that of silicon oxide, but is not limited thereto.

In some example embodiments, the first wiring structure IS1 may include a first wiring 132 in the sensor array region SAR. The first wiring 132 may be electrically connected to the unit pixel of the sensor array region SAR. For example, the first wiring 132 may be connected to the first electronic device TR1.

The first wiring 132 may include at least one of tungsten (W), copper (Cu), aluminum (Al), gold (Au), silver (Ag) or their alloy, but is not limited thereto.

The surface insulating film 140 may be formed on the first surface 110a of the substrate 110. The surface insulating film 140 may be extended along the first surface 110a of the substrate 110. In some example embodiments, at least a portion of the surface insulating film 140 may be in contact with the separation pattern 120.

The surface insulating film 140 may include an insulating material. For example, the surface insulating film 140 may include at least one of silicon oxide, silicon nitride, silicon oxynitride, aluminum oxide, hafnium oxide or their combination, but is not limited thereto. Although not shown in detail, the surface insulating film 140 may be formed of multi-film.

The surface insulating film 140 functions as an anti-reflective film to prevent or reduce the impact from and/or the occurrence of reflection of light incident on the first substrate 110, thereby improving a light receiving rate of the photoelectric conversion layer PD. Also, the surface insulating film 140 functions as a planarization film to form the first color filter 170 and the micro-lens 180, which will be described later, at a uniform height.

The first metal layer 150A may be formed on the surface insulating film 140 of the light receiving region APS. The first metal layer 150A may be disposed on the first surface 110a of the substrate 110 between the grid patterns 160A that will be described later. An upper surface of the first metal layer 150A may be in contact with the first color filter 170, which will be described later, but may not be in contact with the grid patterns 160A. The first metal layer 150A may include at least one of titanium (Ti), titanium nitride (TiN), tantalum (Ta), tantalum nitride (TaN) or their combination.

In the light receiving region APS, the grid patterns 160A may be arranged on the first surface 110a of the substrate 110. The grid patterns 160A may be formed on the surface insulating film 140. When viewed in a plan view, the grid pattern 160 may be formed in a grid shape and disposed on the first color filter 170.

The grid patterns 160A may include first and second grid patterns 160A1 and 160A2, which are spaced apart from each other on the first surface 110a of the substrate 110. One end of the first metal layer 150A may be in contact with the first grid pattern 160A1. However, another end of the first metal layer 150A may be spaced apart from the second grid pattern 160A2.

The grid patterns 160A may include a low refractive index material having a refractive index lower than that of silicon (Si). For example, the grid patterns 160A may include at least one of silicon oxide, aluminum oxide, tantalum oxide or their combination, but are not limited thereto. The grid patterns 160A containing a low refractive index material may improve quality of the image sensor by refracting or reflecting light obliquely incident on the image sensor.

The metal structure 150B may be disposed on the first surface 110a of the substrate 110 in the light blocking region OB. The metal structure 150B may be disposed to be spaced apart from the grid patterns 160A of the light receiving region APS.

The metal structure 150B may include a barrier layer 151 on the surface insulating film 140, a second metal layer 152 on the barrier layer 151, and a third metal layer 153 surrounding the barrier layer 151 and the second metal layer 152.

A thickness of the metal structure 150B in the third direction Z, for example, a sum of thicknesses of the barrier layer 151, the second metal layer 152 and the third metal layer 153 may be, for example, hundreds to thousands of angstroms, but example embodiments are not limited thereto.

Each of the barrier layer 151 and the third metal layer 153 may independently or concurrently include at least one of titanium (Ti), titanium nitride (TiN), tantalum (Ta), tantalum nitride (TaN) or their combination. The second metal layer 152 may include at least one of tungsten (W), aluminum (Al), copper (Cu) or their combination.

For example, titanium (Ti) contents of the barrier layer 151 and the third metal layer 153 may be different from each other, and titanium nitride (TiN) contents of the barrier layer 151 and the third metal layer 153 may be different from each other. In this case, the barrier layer 151 may include titanium nitride (TiN) more than titanium (Ti), and the third metal layer 153 may include titanium (Ti) more than titanium nitride (TiN), but the technical spirits of the present disclosure are not limited thereto.

As will be described later, since the first metal layer 150A and the third metal layer 153 are formed by the same process, the first metal layer 150A and the third metal layer 153 may include the same material; in some example embodiments, the first metal layer 150A and the third metal layer 153 may not include a different material.

The dielectric material layer 160B may be disposed on the metal structure 150B in the light blocking region OB. The dielectric material layer 160B may be disposed to be spaced apart from the grid patterns 160A in the light receiving region APS. The dielectric material layer 160B may be integrally formed on a side and an upper surface of the metal structure 150B. In this case, the dielectric material layer 160B may surround the side and the upper surface of the metal structure 150B, but is not limited thereto. The dielectric material layer 160B may be disposed on only the side without being disposed on the upper surface of the metal structure 150B. For example, a thickness of the dielectric material layer 160B in the third direction Z may be 1000 to thousands of angstroms, but is not limited thereto.

As will be described later, since the grid patterns 160A and the dielectric material layer 160B are formed by the same process, the grid patterns 160A and the dielectric material layer 160B may include the same material.

Referring to FIG. 6, one end portion of the first metal layer 150A may not be indented into the first grid pattern 160A1. For example, the first metal layer 150A may not be disposed inside the first grid pattern 160A1. When viewed in a plan view, the first metal layer 150A and the first grid pattern 160A1 may not overlap each other.

For example, a width W11 of the first grid pattern 160A1 may be 100 to hundreds of nm. A height T11 of the first grid pattern 160A1 may be 1000 to thousands of angstroms. A height T12 of the first metal layer 150A may be hundreds to thousands of angstroms, but the technical spirits of inventive concepts are not limited thereto.

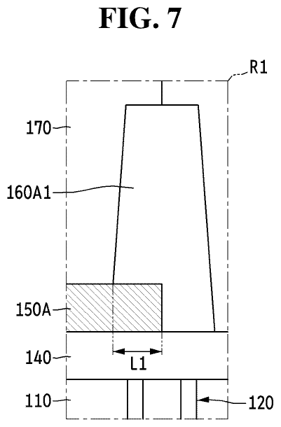

Referring to FIG. 7, one end portion of the first metal layer 150A may be indented into the inside of the first grid pattern 160A1 by a first length L1 smaller than a width of a lower surface of the first grid pattern 160A1. For example, the first metal layer 150A may be disposed inside the first grid pattern 160A1 by the first length L1 smaller than the width of the lower surface of the first grid pattern 160A1.

When viewed in a plan view, the first metal layer 150A and the first grid pattern 160A1 may partially overlap each other. The first metal layer 150 and the first grid pattern 160A1 may overlap each other by the first length L1 in a horizontal direction. In this case, the first length L1 may be a length corresponding to a distance from an outer sidewall of the first grid pattern 160A1 to a center of the separation pattern 120.

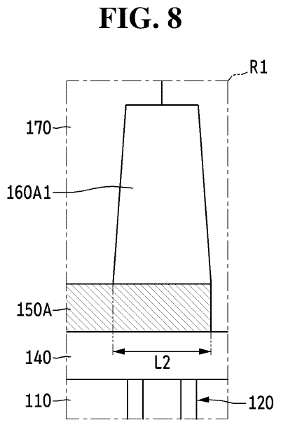

Referring to FIG. 8, one end portion of the first metal layer 150A may be indented into the inside of the first grid pattern 160A1 by a second length L2 corresponding to the width of the lower surface of the first grid pattern 160A1. For example, the first metal layer 150A may be disposed inside the first grid pattern 160A1 by the second length L2 corresponding to the width of the lower surface of the first grid pattern 160A1.

When viewed in a plan view, the first metal layer 150A and the first grid pattern 160A1 may overlap each other by the second length L2 in the horizontal direction. In this case, the second length L2 may be a length corresponding to the width of the lower surface of the first grid pattern 160A1.

As will be described later, in some example embodiments, a first pre-metal layer 150AP and a first pre-dielectric material layer 160AP may not be patterned integrally but be patterned in different processes. For example, the first metal layer 150A and the grid patterns 160A may be formed in different processes. Accordingly, as described in FIGS. 6 to 8, various overlap regions between the first metal layer 150A and the grid patterns 160A may be implemented.

The first color filter 170 may be formed on the surface insulating film 140 of the light receiving region APS. The first color filter 170 may be disposed on the grid patterns 160A and the first metal layer 150A. In some example embodiments, the first color filter 170 may be disposed on the plurality of unit pixel regions PX1 to PX4. Although not shown in detail, a plurality of first color filters 170 may be arranged two-dimensionally (e.g., in the form of a matrix) on a plane including the first direction X and the second direction Y.

The first color filter 170 may have various color filters depending on the pixel group PG. For example, the first color filter 170 may be arranged in a Bayer pattern including a red color filter, a green color filter, and a blue color filter. However, this is only an example, and the first color filter 170 may include a yellow filter, a magenta filter, and a cyan filter.

The micro-lens 180 may be disposed on the first color filter 170. The micro-lens 180 may have a convex shape, and may have a predetermined radius of curvature. Accordingly, the micro-lens 180 may condense light incident on the photoelectric conversion layer PD. The micro-lens 180 may include, for example, a light transmitting resin, but is not limited thereto.

In some example embodiments, a first passivation film 185 may be disposed on the micro-lens 180. The first passivation film 185 may be extended along a surface of the micro-lens 180. The first passivation film 185 may include, for example, an inorganic oxide film. For example, the first passivation film 185 may include at least one of silicon oxide, titanium oxide, zirconium oxide, hafnium oxide or their combination, but is not limited thereto. In some example embodiments, the first passivation film 185 may include low temperature oxide (LTO).

The first passivation film 185 may protect the micro-lens 180 from the outside. For example, the first passivation film 185 may include the inorganic oxide film to protect the micro-lens 180 containing an organic material. In addition, the first passivation film 185 may improve light condensing capability of the micro-lens 180. For example, the first passivation film 185 may fill a space between the micro-lenses 180 to reduce reflection, refraction, scattering and the like of incident light reaching the space between the micro-lenses 180.

A second color filter 170C may be formed on the surface insulating film 140 of the light blocking region OB and the connection region CR. The second color filter 170C may include, for example, a blue color filter, but is not limited thereto.

In some example embodiments, a second passivation film 380 may be formed on the second color filter 170C. In some example embodiments, the first passivation film 185 may be extended along a surface of the second passivation film 380. The second passivation film 380 may include, for example, a light transmitting resin, but is not limited thereto. In some example embodiments, the second passivation film 380 may include the same material as that of the micro-lens 180.

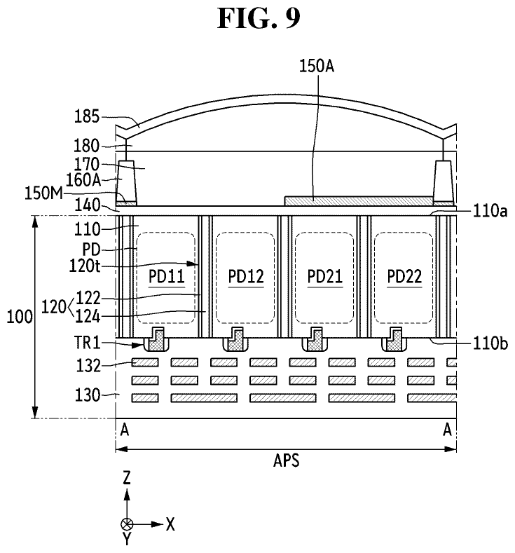

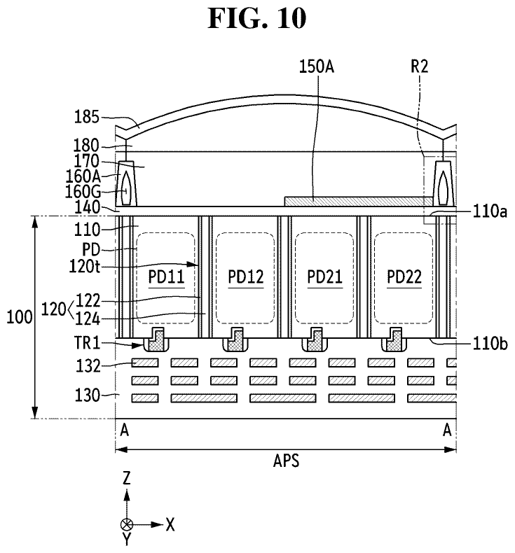

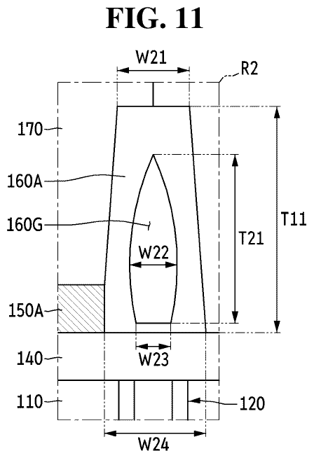

FIGS. 9 and 10 are cross-sectional views illustrating an image sensor according to some example embodiments. FIG. 11 is an enlarged view illustrating a region R2 of FIG. 10. For convenience of description, redundant portions of those described with reference to FIGS. 1 to 8 will be briefly described or omitted.

Referring to FIG. 9, the image sensor according to some example embodiments may further include a metal film 150M.

The metal film 150M may be disposed between at least one of the grid patterns 160A and the surface insulating film 140 in the light receiving region APS. For example, a thickness of the metal film 150M may be less than a thickness of the first metal layer 150A. For example, the metal film 150M may include at least one of Ti or TiN.

Referring to FIGS. 10 and 11, in the image sensor according to some example embodiments, at least one of the grid patterns 160A may include an air gap 160G. In some example embodiments, the air gap 160G may include air, such as but not limited to clean, dry air; example embodiments are not limited thereto.

A width W24 of a lower surface of the first grid pattern 160A1 may be greater than a width W21 of an upper surface of the first grid pattern 160A1.

A maximum width W22 of the air gap 160G may be greater than a lower width W23 of the air gap 160G and smaller than the width W21 of the upper surface of the first grid pattern 160A1. For example, the maximum width W22 of the air gap 160G may be about 80 nm or less, but is not limited thereto.

A length T21 of the air gap 160G in the third direction Z may be less than a length T11 of the first grid pattern 160A1 in the third direction Z. For example, the length T21 of the air gap 160G in the third direction Z may be about 3300 angstroms, and the length T11 of the first grid pattern 160A1 in the third direction Z may be about 3600 angstroms, but example embodiments are not limited thereto.

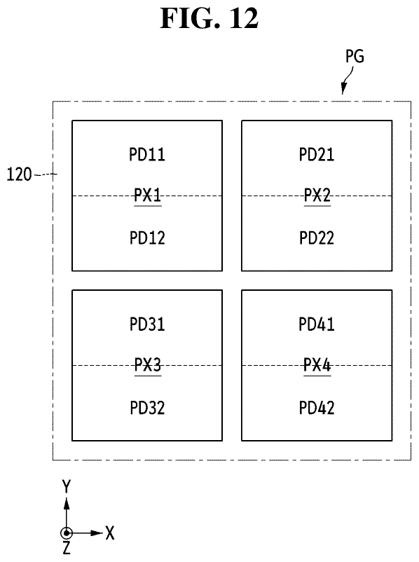

FIG. 12 is a layout view illustrating an image sensor according to some example embodiments. For convenience of description, redundant portions of those described with reference to FIGS. 1 to 11 will be briefly described or omitted.

Referring to FIG. 12, the first unit pixel region PX1 may include (1_1)th and (1_2)th photoelectric conversion layers PD11 and PD12 adjacent to each other in the second direction Y. Long sides of each of the (1_1)th and (1_2)th photoelectric conversion layers PD11 and PD12 may be extended in the first direction X, and short sides thereof may be extended in the second direction Y.

The second unit pixel region PX2 may include (2_1)th and (2_2)th photoelectric conversion layers PD21 and PD22 adjacent to each other in the second direction Y. Long sides of each of the (2_1)th and (2_2)th photoelectric conversion layers PD21 and PD22 may be extended in the first direction X, and short sides thereof may be extended in the second direction Y.

The third unit pixel region PX3 may include (3_1)th and (3_2)th photoelectric conversion layers PD31 and PD32 adjacent to each other in the second direction Y. Long sides of each of the (3_1)th and (3_2)th photoelectric conversion layers PD31 and PD32 may be extended in the first direction X, and short sides thereof may be extended in the second direction Y.

The fourth unit pixel region PX4 may include (4_1)th and (4_2)th photoelectric conversion layers PD41 and PD42 adjacent to each other in the second direction Y. Long sides of each of the (4_1)th and (4_2)th photoelectric conversion layers PD41 and PD42 may be extended in the first direction X, and short sides thereof may be extended in the second direction Y.

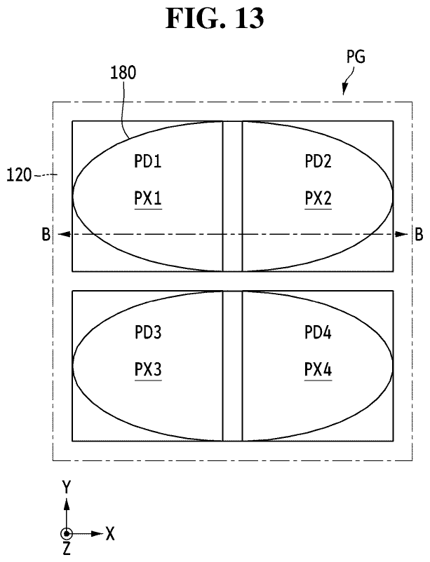

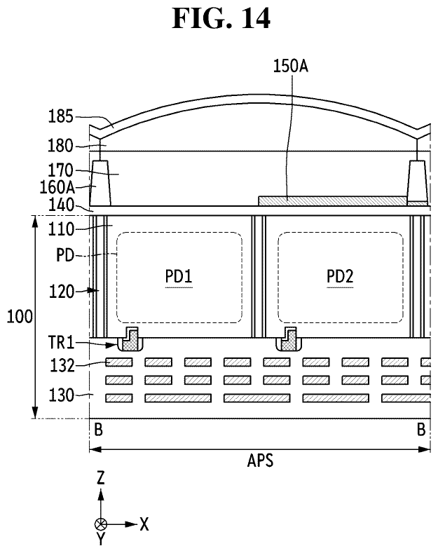

FIG. 13 is a layout view illustrating an image sensor according to some example embodiments. FIG. 14 is a cross-sectional view taken along line B-B of FIG. 13. For convenience of description, redundant portions of those described with reference to FIGS. 1 to 12 will be briefly described or omitted.

Referring to FIGS. 13 and 14, each of the plurality of unit pixel regions PX1, PX2, PX3 and PX4 may include one, e.g., one or more of, e.g., precisely one per region, photoelectric conversion layer PD1 to PD4. The first unit pixel region PX1 may include a first photoelectric conversion layer PD1, the second unit pixel region PX2 may include a second photoelectric conversion layer PD2, the third unit pixel region PX3 may include a third photoelectric conversion layer PD3, and the fourth unit pixel region PX4 may include a fourth photoelectric conversion layer PD4.

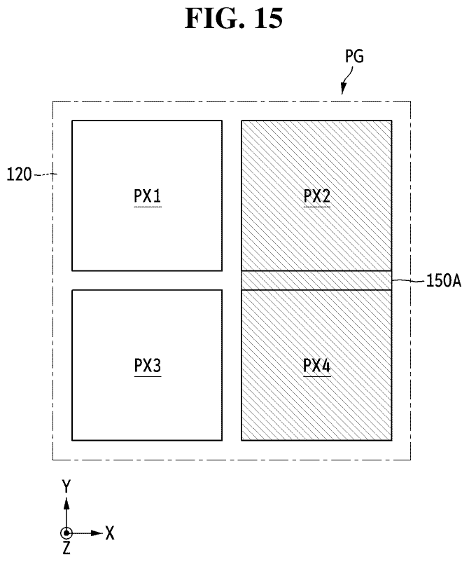

FIGS. 15 to 22 are layout views illustrating an image sensor according to some example embodiments. For convenience of description, redundant portions of those described with reference to FIGS. 1 to 14 will be briefly described or omitted. For reference, right, left, upper and lower regions described in example embodiments may be understood in view of the plan view shown in FIGS. 15 to 22.

Referring to FIG. 15, in the light receiving region APS, the first metal layer 150A may be extended on the second and fourth unit pixel regions PX2 and PX4 adjacent to each other in the second direction Y among the plurality of unit pixel regions PX1 to PX4.

The first metal layer 150A may be extended on the separation pattern 120 between the second and fourth unit pixel regions PX2 and PX4 and between the second and fourth unit pixel regions PX2 and PX4. The first metal layer 150A may not be disposed on the first and third unit pixel regions PX1 and PX3.

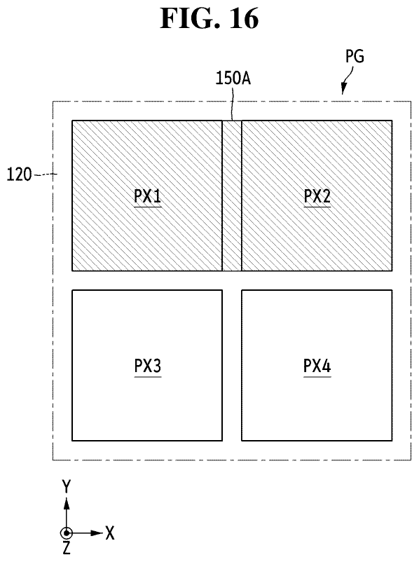

Referring to FIG. 16, the first metal layer 150A may be extended on the first and second unit pixel regions PX1 and PX2 adjacent to each other in the first direction X among the plurality of unit pixel regions PX1 to PX4.

The first metal layer 150A may be extended on the first and second unit pixel regions PX1 and PX2 and the separation pattern 120 therebetween. The first metal layer 150A may not be disposed on the third and fourth unit pixel regions PX3 and PX4.

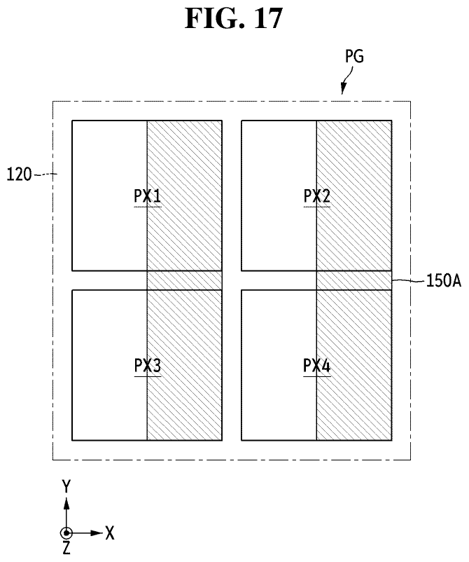

Referring to FIG. 17, the first metal layer 150A may be extended in the second direction Y on right regions of the first and third unit pixel regions PX1 and PX3 and right regions of the second and fourth unit pixel regions PX2 and PX4.

The first metal layer 150A may be extended on the right regions of the first and third unit pixel regions PX1 and PX3 and the separation pattern 120 therebetween. The first metal layer 150A may be extended on the right regions of the second and fourth unit pixel regions PX2 and PX4 and the separation pattern therebetween.

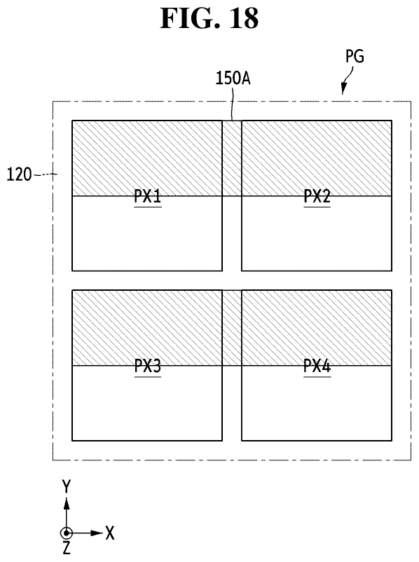

Referring to FIG. 18, the first metal layer 150A may be extended in the first direction X on upper regions of the first and second unit pixel regions PX1 and PX2 and upper regions of the third and fourth unit pixel regions PX3 and PX4.

The first metal layer 150A may be extended on the upper regions of the first and second unit pixel regions PX1 and PX2 and the separation pattern 120 therebetween. The first metal layer 150A may be extended on the upper regions of the third and fourth unit pixel regions PX3 and PX4 and the separation pattern 120 therebetween.

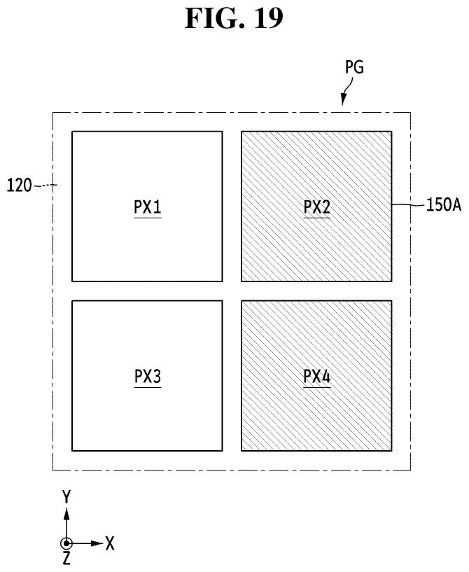

Referring to FIG. 19, the first metal layer 150A may be extended in the second direction Y on the second and fourth unit pixel regions PX2 and PX4 adjacent to each other in the second direction Y.

The first metal layer 150A may not be extended on the separation pattern 120 between the second and fourth unit pixel regions PX2 and PX4.

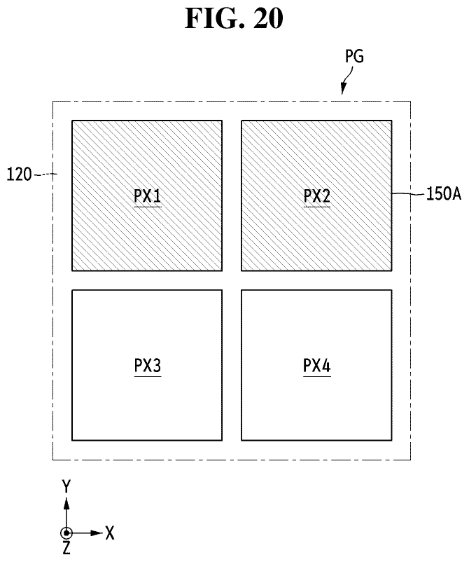

Referring to FIG. 20, the first metal layer 150A may be extended in the first direction X on the first and second unit pixel regions PX1 and PX2 adjacent to each other in the first direction X.

The first metal layer 150A may not be extended on the separation pattern 120 between the first and second unit pixel regions PX1 and PX2.

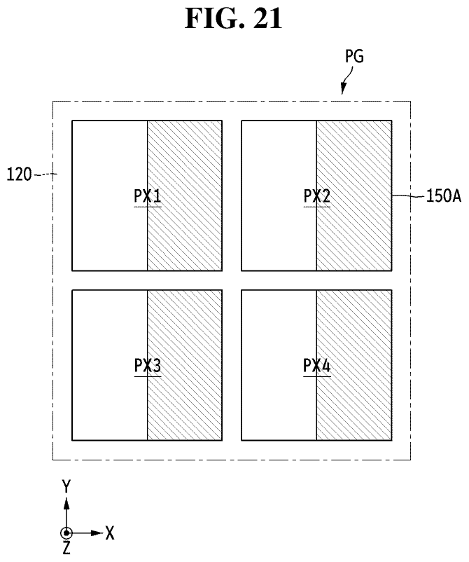

Referring to FIG. 21, the first metal layer 150A may be extended in the second direction Y on the right region of each of the second and fourth unit pixel regions PX2 and PX4 adjacent to each other in the second direction Y. The first metal layer 150A may be extended in the second direction Y on the right region of each of the first and third unit pixel regions PX1 and PX3 adjacent to each other in the second direction Y.

The first metal layer 150A may not be extended on the separation pattern 120 between the second and fourth unit pixel regions PX2 and PX4. The first metal layer 150A may not be extended on the separation pattern 120 between the first and third unit pixel regions PX1 and PX3.

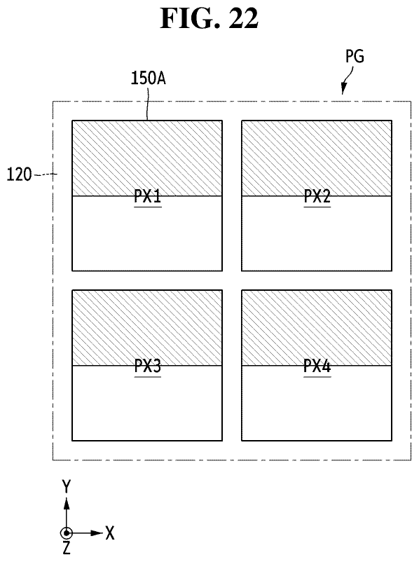

Referring to FIG. 22, the first metal layer 150A may be extended in the first direction X on the upper region of each of the first and second unit pixel regions PX1 and PX2 adjacent to each other in the first direction X. The first metal layer 150A may be extended in the first direction X on the upper region of each of the third and fourth unit pixel regions PX1 and PX3 adjacent to each other in the first direction X.

The first metal layer 150A may not be extended on the separation pattern 120 between the first and second unit pixel regions PX1 and PX2. The first metal layer 150A may not be extended on the separation pattern 120 between the third and fourth unit pixel regions PX1 and PX3.

Meanwhile, although not shown in detail, the above description may be also applied to a case that the first metal layer 150A is extended to a left region and a lower region of each unit pixel region.

In addition, although not shown in detail, the first metal layer 150A described with reference to FIGS. 15 to 22 may be applied to an image sensor that includes a nano prism.

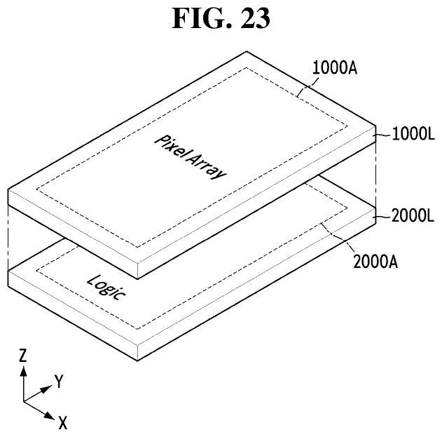

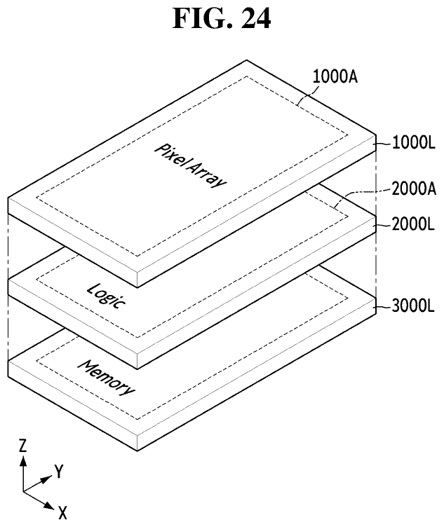

FIGS. 23 and 24 are views illustrating a conceptual layout of an image sensor according to some example embodiments. For convenience of description, redundant portions of those described with reference to FIGS. 1 to 22 will be briefly described or omitted.

Referring to FIG. 23, the image sensor according to some example embodiments may include a first layer 1000L and a second layer 2000L. The second layer 2000L and the first layer 1000L may be stacked in the third direction Z and thus electrically connected to each other.

The first layer 1000L may include a pixel array 1000A in which a plurality of pixels are disposed in a 2D array structure. The pixel array 1000A may correspond to the active pixel sensor array 10 of FIG. 1.

The second layer 2000L may include a logic region 2000A in which logic devices are disposed. The logic devices included in the logic region 2000A may be electrically connected to the pixel array 1000A to provide a signal to the pixel or process the signal output from the pixel. For example, electronic devices constituting the row decoder 20, the row driver 30, the column decoder 40, the timing generator 50, the correlated double sampler 60, the analog-to-digital converter 70, or the input/output buffer 80 of FIG. 1 may be included in the logic region 2000A.

Referring to FIG. 24, the image sensor according to some example embodiments may include a first layer 1000L, a second layer 2000L, and a third layer 3000L. The third layer 3000L, the second layer 2000L and the first layer 1000L may be stacked in the third direction Z.

The third layer 3000L may include a memory device. For example, the third layer 3000L may include volatile memory devices such as DRAM and SRAM. The third layer 3000L may receive signals from the first layer 1000L and the second layer 2000L and process the signals through the memory device. That is, the image sensor may be a three-stack image sensor that includes three layers 1000L, 2000L and 3000L.

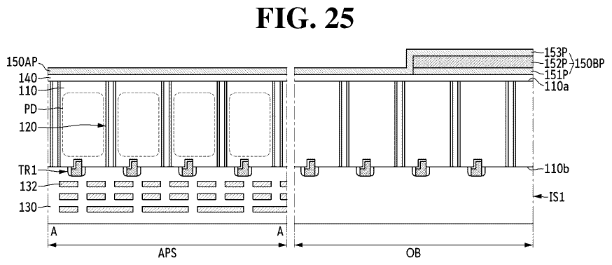

FIGS. 25 to 29 are views illustrating intermediate steps or operations to describe a manufacturing method of an image sensor according to some example embodiments. For convenience of description, redundant portions of those described above with reference to FIGS. 1 to 24 will be briefly described or omitted.

Referring to FIG. 25, a substrate 110 including photoelectric conversion layers PD and including a first surface 110a and a second surface 110b, which are opposite to each other, may be provided.

The substrate 110 may be formed on a first wiring structure IS1 that includes a first wiring 132 in a first inter-wire insulating layer 130. A unit pixel of a sensor array region SAR of FIG. 3 and a first electronic device TR1 may be electrically connected to each other through the first wiring 132.

A surface insulating film 140 may be formed on the first surface 110a of the substrate 110. The surface insulating film 140 may be formed in both a light receiving region APS and a light blocking region OB of the substrate 110.

A first pre-barrier layer 151P and a second pre-metal layer 152P may be sequentially formed, e.g., locally formed. on the surface insulating film 140 of the light blocking region OB.

Afterwards, a first pre-metal layer 150AP may be formed, e.g., conformally formed, on the surface insulating film 140 in the light-receiving region APS, and a third pre-metal layer 153P may be formed on the surface insulating film 140 and the second pre-metal layer 152P in the light blocking region OB.

The first pre-metal layer 150AP and the third pre-metal layer 153P may be formed by the same process, such as one or more of a chemical vapor deposition (CVD) process, an atomic layer deposition (ALD) process, or a physical vapor deposition (PVD) process. The first pre-metal layer 150AP and the third pre-metal layer 153P may include the same material.

Therefore, a pre-metal structure 150BP, which includes the first pre-barrier layer 151P, the second pre-metal layer 152P and the third pre-metal layer 153P, may be formed in the light blocking region OB.

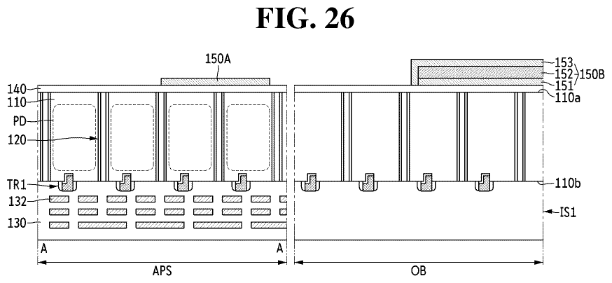

Referring to FIG. 26, at least a portion of the first pre-metal layer 150AP and the third pre-metal layer 153P of FIG. 25 may be removed, e.g., may be etched, to form the first metal layer 150A and the metal structure 150B. As at least a portion of the first pre-metal layer 150AP and the third pre-metal layer 153P is removed, an upper surface of the surface insulating film 140 except for the regions in which the first metal layer 150A and the metal structure 150B are formed may be exposed.

Therefore, the first metal layer 150A may be formed in a partial region on the surface insulating film 140 of the light receiving region APS. The metal structure 150BP, which includes the first barrier layer 151, the second metal layer 152 and the third metal layer 153, may be formed in the partial region on the surface insulating film 140 of the light blocking region OB.

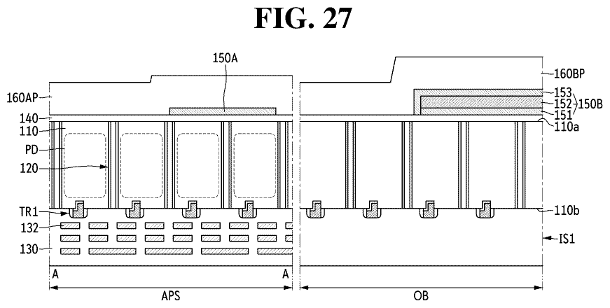

Referring to FIG. 27, a first pre-dielectric material layer 160AP on the first metal layer 150A may be formed in the light receiving region APS, and a second pre-dielectric material layer 160BP on the metal structure 150B may be formed in the light blocking region OB. The first pre-dielectric material layer 160AP may cover an exposed upper surface of the surface insulating film 140 and the first metal layer 150A. The second pre-dielectric material layer 160BP may cover the exposed upper surface of the surface insulating film 140 and the metal structure 150B. The first and second pre-dielectric material layers 160AP and 160BP may be formed in the same process; however, example embodiments are not limited thereto.

An upper surface of the first pre-dielectric material layer 160AP may be further protruded from a portion corresponding to the first metal layer 150A, and the second pre-dielectric material layer 160BP may be further protruded from a portion corresponding to the metal structure 150B, but the present disclosure is not limited thereto.

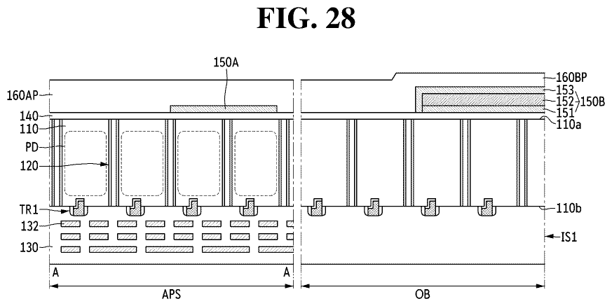

Referring to FIG. 28, at least a portion of each of an upper portion of the first pre-dielectric material layer 160AP and an upper portion of the second pre-dielectric material layer 160BP may be removed.

This may include a planarization process, such as a chemical mechanical planarization (CMP) process and/or an etch-back process, performed on the upper surface of the first pre-dielectric material layer 160AP and the upper surface of the second pre-dielectric material layer 160BP. Accordingly, a step difference between the upper surface of the first pre-dielectric material layer 160AP and the upper surface of the second pre-dielectric material layer 160BP may be reduced.

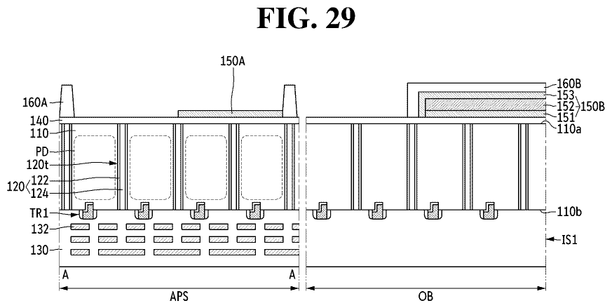

Referring to FIG. 29, in the light receiving region APS, at least a portion of the first pre-dielectric material layer 160AP may be removed so that grid patterns 160A may be formed. In the light blocking region OB, at least a portion of the second pre-dielectric material layer 160BP may be removed so that the dielectric material layer 160BP may be formed. This may be performed using a photo process.

In the light receiving region APS, the grid patterns 160A may expose the upper surface of the first metal layer 150A. In the light blocking region OB, the dielectric material layer 160B may be disposed on the metal structure 150B.

Although not shown in detail, the second pre-dielectric material layer 160BP on the upper surface of the metal structure 150B may be further removed. In this case, the dielectric material layer 160B may be disposed only on the side of the metal structure 150B without being disposed on the upper surface thereof.

In some example embodiments, the first pre-metal layer 150AP and the first pre-dielectric material layer 160AP may be patterned in different processes. For example, the first metal layer 150A and the grid patterns 160A may be formed in different processes. Accordingly, various structures may be implemented in the first metal layer 150A and the grid patterns 160A.

Then, a first color filter 170 and a micro-lens 180 may be further formed on the surface insulating film 140. As a result, the image sensor described with reference to FIG. 5 may be manufactured.

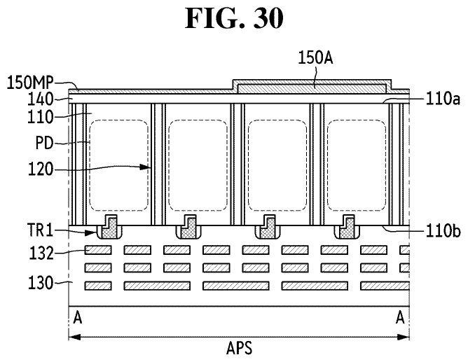

FIGS. 30 to 33 are views illustrating intermediate steps or operations to describe a manufacturing method of an image sensor according to some example embodiments. For convenience of description, redundant portions of those described above with reference to FIGS. 1 to 29 will be briefly described or omitted.

For reference, FIG. 30 is a view illustrating a process after the first metal layer 150A is formed.

Referring to FIG. 30, in the light receiving region APS, a pre-metal film 150MP may be further formed on the upper surface of the surface insulating film 140 and the first metal layer 150A. The pre-metal film 150MP may cover the exposed upper surface of the surface insulating film 140, the side of the first metal layer 150A and the upper surface of the first metal layer 150A.

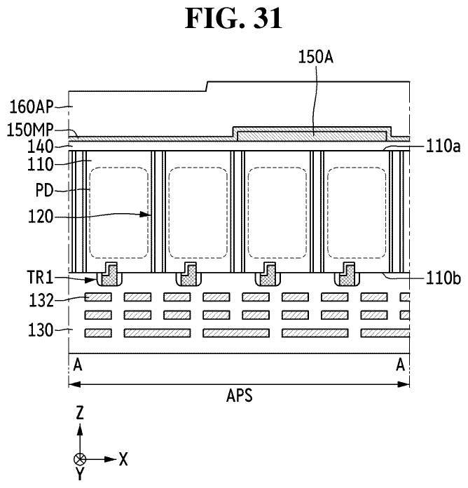

Referring to FIG. 31, the first pre-dielectric material layer 160AP on the pre-metal film 150MP and the first metal layer 150A may be formed in the light receiving region APS. The upper surface of the first pre-dielectric material layer 160AP may be further protruded from the portion corresponding to the first metal layer 150A, but is not limited thereto.

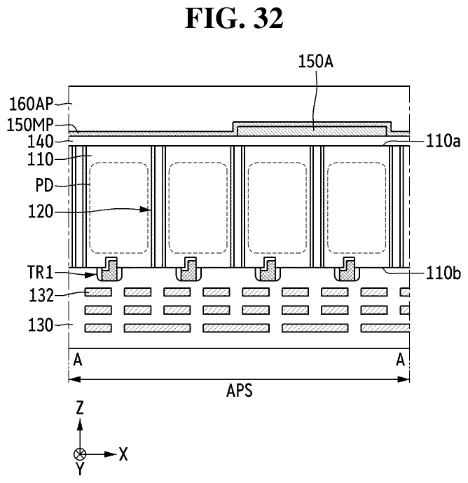

Referring to FIG. 32, at least a portion of the upper portion of the first pre-dielectric material layer 160AP may be removed. This may include a planarization process performed on the upper surface of the first pre-dielectric material layer 160AP. Accordingly, a step difference of the upper surface of the first pre-dielectric material layer 160AP may be reduced.

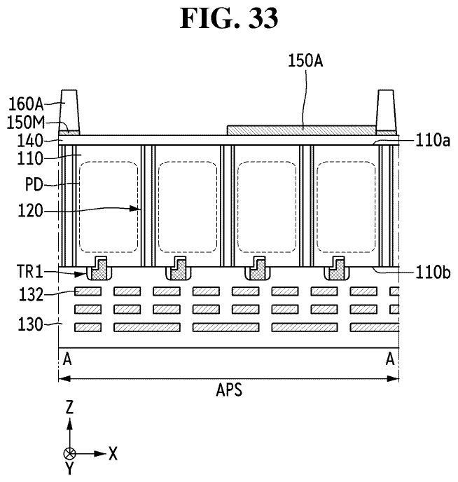

Referring to FIG. 33, at least a portion of the first pre-dielectric material layer 160AP may be removed so that grid patterns 160A may be formed in the light receiving region APS. Also, at least a portion of the pre-metal film 150MP may be removed so that a metal film 150M may be formed in the light receiving region APS.

Therefore, the metal film 150M interposed between the surface insulating film 140 and the grid patterns 160A may be formed.

In some example embodiments, the first metal layer 150A and the grid patterns 160A may be formed in different processes. Accordingly, various structures of the first metal layer 150A and the grid patterns 160A may be implemented. For example, as described above with reference to FIGS. 9 and 30 to 33, the metal film 150M may be disposed below the grid patterns 160A. In this case, optical characteristics of the image sensor may be improved by reducing noise between adjacent unit pixel regions.

Afterwards, a first color filter 170 and a micro-lens 180 may be further formed on the surface insulating film 140. As a result, the image sensor described with reference to FIG. 9 may be manufactured.

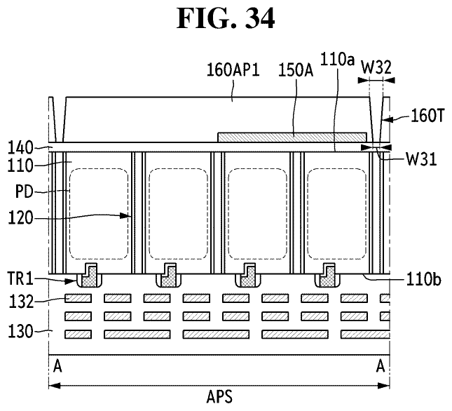

FIGS. 34 to 36 are views illustrating intermediate steps or operations to describe a manufacturing method of an image sensor according to some example embodiments. For convenience of description, redundant portions of those described above with reference to FIGS. 1 to 33 will be briefly described or omitted.

For reference, FIG. 34 is a view illustrating a process after the first metal layer 150A and a first pre-dielectric material layer 160AP1 are formed. The first pre-dielectric material layer 160AP1 of FIG. 34 may correspond to the first pre-dielectric material layer 160AP described above.

Referring to FIG. 34, a portion of the first pre-dielectric material layer 160AP1 may be removed to form a trench 160T for exposing the upper surface of the surface insulating film 140. Since the trench 160T is formed from an upper portion of the first pre-dielectric material layer 160AP1, an upper width W32 of the trench 160T may be greater than a lower width W31. For example, a length of the lower width W31 may be about 80 nm, and a length of the upper width W32 may be about 150 nm to 200 nm, but the present disclosure is not limited thereto.

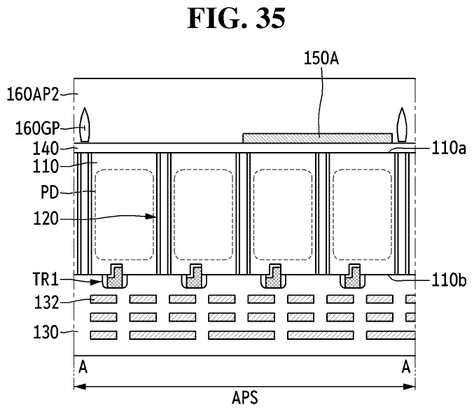

Referring to FIG. 35, a second pre-dielectric material layer 160AP2 may be formed on the first pre-dielectric material layer 160AP1.

The second pre-dielectric material layer 160AP2 may be formed on the first pre-dielectric material layer 160AP1 while filling at least a portion of the inside of the trench 160T. However, the second pre-dielectric material layer 160AP2 may not completely fill the inside of the trench 160T. Accordingly, a pre-air gap 160GP may be formed inside the second pre-dielectric material layer 160AP2.

For example, the first pre-dielectric material layer 160AP1 and the second pre-dielectric material layer 160AP2 may include the same material. In this case, an interface between the first pre-dielectric material layer 160AP1 and the second pre-dielectric material layer 160AP2 may not exist, but example embodiments are not limited thereto.

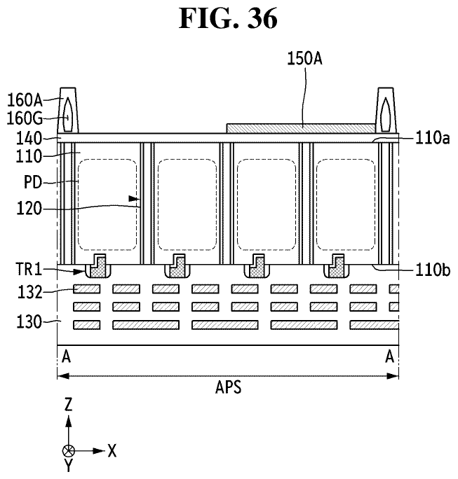

Referring to FIG. 36, at least a portion of the second pre-dielectric material layer 160AP2 may be removed. Accordingly, grid patterns 160A including the air gap 160G may be formed in the light receiving region APS.

In some example embodiments, the first metal layer 150A and the grid patterns 160A may be formed in different processes. Accordingly, various structures of the first metal layer 150A and the grid patterns 160A may be implemented. For example, as described above with reference to FIGS. 10 and 34 to 36, the grid patterns 160A having the air gap 160G may be formed. For example, at least one of the grid patterns 160A may surround the air gap 160G. In this case, since there is an effect of reducing a refractive index of the entire grid pattern, optical characteristics of the image sensor may be improved. Meanwhile, a region of the air gap 160G is not limited to the shown example, and may be formed in various sizes depending on desired optical characteristics.

Then, a first color filter 170 and a micro-lens 180 may be further formed on the surface insulating film 140. As a result, the image sensor described with reference to FIG. 10 may be manufactured.

Although some example embodiments have been described with reference to the accompanying drawings, it will be apparent to those of ordinary skill in the art that example embodiments can be manufactured and/or implemented in various forms without being limited to the above-described example embodiments and can be embodied in other specific forms without departing from technical spirits and/or essential characteristics. Thus, the above example embodiments are to be considered in all respects as illustrative and not restrictive. Additionally, example embodiments are not necessarily mutually exclusive with one another. For example, some example embodiments may include one or more features described with reference to one or more figures, and may also include one or more other features described with reference to one or more other figures.

What is claimed is:

1. An image sensor comprising:
a substrate including a first region and a second region, the substrate including first and second surfaces opposite to each other;
a plurality of unit pixel regions including photoelectric conversion layers inside the substrate;
grid patterns in the first region and on the first surface of the substrate;
a first metal layer in the first region, on the first surface of the substrate and between the grid patterns;
a metal structure on the first surface of the substrate, in the second region, and spaced apart from the grid patterns; and
a color filter on the grid patterns and the first metal layer.

2. The image sensor of claim 1, wherein an upper surface of the first metal layer is in contact with the color filter and is not in contact with the grid patterns.

3. The image sensor of claim 1, further comprising:
a surface insulating film on the first surface of the substrate,
wherein the metal structure includes a barrier layer on the surface insulating film, a second metal layer on the barrier layer, and a third metal layer surrounding the barrier layer and the second metal layer.

4. The image sensor of claim 1, further comprising:
a dielectric material layer in the second region, spaced apart from the grid patterns, and on the metal structure,
wherein the dielectric material layer includes a same material as that of the grid patterns.

5. The image sensor of claim 1, wherein
the grid patterns include first and second grid patterns spaced apart from each other on the first surface of the substrate, and
one end portion of the first metal layer is in contact with the first grid pattern, and another end portion of the first metal layer is spaced apart from the second grid pattern.

6. The image sensor of claim 5, wherein one end portion of the first metal layer is not indented into at least one of the first and second grid patterns.

7. The image sensor of claim 5, wherein one end portion of the first metal layer is indented into the first grid pattern by a first length less than a width of a lower surface of the first grid pattern.

8. The image sensor of claim 5, wherein one end portion of the first metal layer is indented into the first grid pattern by a second length corresponding to a width of a lower surface of the first grid pattern.

9. The image sensor of claim 1, further comprising:
a metal film between the grid patterns and the first surface of the substrate.

10. The image sensor of claim 1, wherein at least one of the grid patterns surrounds an air gap.

11. The image sensor of claim 10, wherein a maximum width of the air gap is greater than a lower width of the air gap and less than a width of an upper surface of any one of the grid patterns.

12. The image sensor of claim 1, wherein each of the plurality of unit pixel regions includes at least one photoelectric conversion layer.

13. The image sensor of claim 1, wherein each of the plurality of unit pixel regions includes a plurality of photoelectric conversion layers.

14. An image sensor comprising:
a substrate including a light receiving region and a light blocking region, extended in first and second directions crossing each other;
a plurality of unit pixel regions including photoelectric conversion layers arranged in the first and second directions;
a first metal pattern extended on some unit pixel regions adjacent to each other in the first direction, among the plurality of unit pixel regions in the light receiving region; and
grid patterns exposing an upper surface of the first metal pattern in the light receiving region.

15. The image sensor of claim 14, further comprising:
a separation pattern extended into the substrate between the photoelectric conversion layers,
wherein, when viewed in a plan view, the first metal pattern extends further on the separation pattern in the first direction.

16. The image sensor of claim 14, wherein
the plurality of unit pixel regions include first and second unit pixel regions adjacent to each other in the first direction, and third and fourth unit pixel regions spaced apart from each of the first and second unit pixel regions in the second direction and adjacent to each other in the first direction, and
the first metal pattern extends on the first and second unit pixel regions but does not extend on the third and fourth unit pixel regions.

17. The image sensor of claim 14, in the light blocking region, further comprising:
a second metal pattern disposed to be spaced apart from the grid patterns; and
a dielectric material layer on a sidewall of the second metal pattern.

18. The image sensor of claim 17, wherein
the second metal pattern includes a barrier layer, a second metal layer on the barrier layer, and a third metal layer surrounding the barrier layer and the second metal layer,
each of the barrier layer and the third metal layer includes at least one of Ti or TiN, and
the dielectric material layer includes the same material as that of the grid patterns.

19. The image sensor of claim 14, wherein
the plurality of unit pixel regions are disposed on the same color filter,
the plurality of unit pixel regions include first and second unit pixel regions adjacent to each other in the second direction, sharing a first micro-lens, and third and fourth unit pixel regions adjacent to each other in the second direction, sharing a second micro-lens.

20. An image sensor comprising:
a substrate including a first region and a second region and including first and second surfaces opposite to each other;
a plurality of unit pixel regions including photoelectric conversion layers inside the substrate;
a surface insulating film disposed on the first surface of the substrate;
grid patterns including first and second grid patterns disposed to be spaced apart from each other on the surface insulating film in the first region;
a first metal layer disposed between the first and second grid patterns on the surface insulating film in the first region;
a metal structure disposed to be spaced apart from the first and second grid patterns on the surface insulating film in the second region;
a dielectric material layer disposed on the metal structure in the second region; and
a color filter disposed on the grid patterns and the first metal layer,
wherein, in the first region, one end portion of the first metal layer is in contact with the first grid pattern, and the other end portion of the first metal layer is spaced apart from the second grid pattern.
